(19) United States
(12) Patent Application Publication
(10) Pub. No.: US 2022/0168677 A1
(43) Pub. Date: Jun. 2, 2022

(54) MACHINE PROTECTION FRAME DEVICE WITH FUNCTION OF AIR FILTERING

(71) Applicants: YI-CHING LIU, Hsinchu (TW); TSUNG-TA LIEN, Hsinchu (TW)

(72) Inventors: YI-CHING LIU, Hsinchu (TW); TSUNG-TA LIEN, Hsinchu (TW)

(21) Appl. No.: 17/107,963

(22) Filed: Dec. 1, 2020

(51) Int. Cl. B01D 46/00; B01D 46/10

(52) U.S. Cl. CPC B01D 46/0002; B01D 46/0043; B01D 46/10; B01D 2279/51; B01D 46/002; B01D 2273/30; B01D 46/0093

(57) ABSTRACT

A mask machine protection frame device with function of air filtering includes an outer frame being a hollow frame for receiving a mask machine therein; an outlook of the outer frame; and at least one air filter installed at an upper side of the outer frame for sucking outer air into the outer frame; the air filter including at least one fan and at least one filter device; the fan serving to suck outer air into the filter device for air filtering so as to flow out clean air; and the clean air then flowing to the mask machine. The outer frame can be installed with at least one fire proof plate and a surface of the fire proof plate is coated with an anti-electric static layer.

### FIELD OF THE INVENTION

The present invention is related to mask machines, and in particular to a mask machine protection frame device with function of air filtering.

### BACKGROUND OF THE INVENTION

In the manufacturing process of semiconductor, mask machines are necessary devices. In operation of mask machine, clean air is an important factor so as to cause generated masks to be perfect and to be safely used in manufacturing of the semiconductor products.

In the prior art mask manufacturing environment, the mask machine is located in an opened space. Although air is filtered as the air is sucked from outer environment, but the air is not perfectly cleaned. As a result, the produced masks are not as pure as to be used in manufacturing of semiconductor safely.

Furthermore, a mask machine has complicated structure and the cost is high. If it is destroyed due to outer environment, the cost for repairing or buying a new one is great. Therefore, it is necessary to provide proper protection to the operation processes of the mask machine, such as fire proof or anti-electric statics. However, currently there are no environment which can provide these protection mechanisms to the operation of the mask machine.

Thus, it is the object of the present invention to provides a newly device which can provide a protect frame to the mask machine with the function of air filter, fire protection and anti-electric statics.

### SUMMARY OF THE INVENTION

Accordingly, for improving above mentioned defects in the prior art, the object of the present invention is to provide a mask machine protection frame device with function of air filtering, wherein the outer frame is installed with air filter which serves to provide pure clean air of the mask machine. Outer sides of the outer frame are equipped with fire proof plates for preventing fire and increasing high temperature in the environment. Furthermore the fire proof plate is installed with an anti-electric static layer which has the function of preventing generation of static electrons so that the mask machine is not affected by static electrons. Therefore, the present invention provides a preferred environment to the operation of the mask machine.

To achieve above object, the present invention provides a mask machine protection frame device with function of air filtering including an outer frame being a hollow frame for receiving a mask machine therein; an outlook of the outer frame; and at least one air filter installed at an upper side of the outer frame for sucking outer air into the outer frame; the air filter including at least one fan and at least one filter device; the fan serving to suck outer air into the filter device for air filtering so as to flow out clean air; and the clean air then flowing to the mask machine. The outer frame can be installed with at least one fire proof plate and a surface of the fire proof plate is coated with an anti-electric static layer.

### BRIEF DESCRIPTION OF THE DRAWINGS

FIG. 1 is a schematic view showing the assembly of the elements of the present invention.

FIG. 2 is an exploded schematic view of the present invention showing the outer frame and the air filters of the present invention.

FIG. 3 is a schematic view showing the application of the present invention.

FIG. 4 is a schematic view showing that the outer frame of the present invention is installed with fire proof plates.

FIG. 5 is a cross section view along line A-A of FIG. 4.

FIG. 6 is a schematic view showing another application of the present invention.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

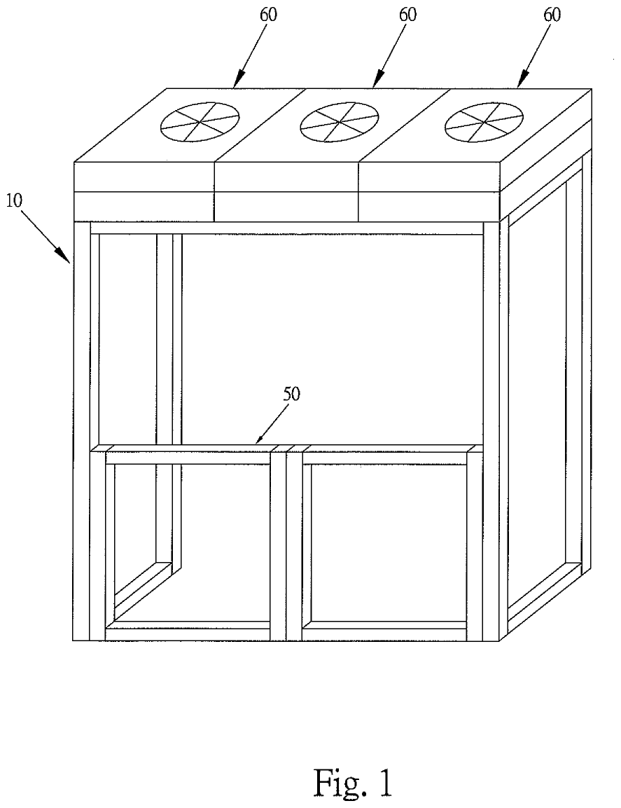

With reference to FIGS. 1 to 6, the structure of the present invention is illustrated. The present invention includes the following elements.

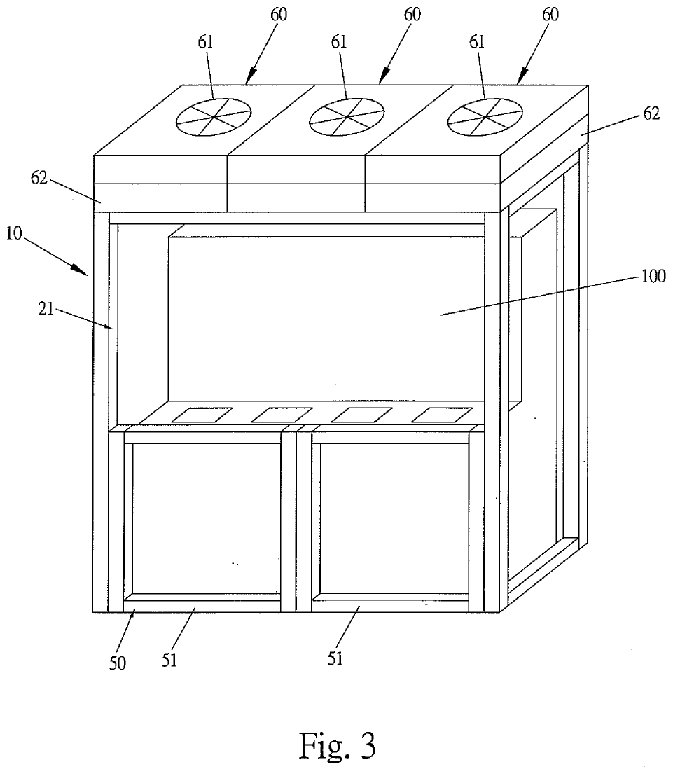

An outer frame 10 is a hollow frame. An internal of the outer frame 10 serves for receiving a mask machine 100, as illustrated in FIG. 3. In the present invention, an outlook of the outer frame 10 may be varied as desired for suiting the mask machine 100.

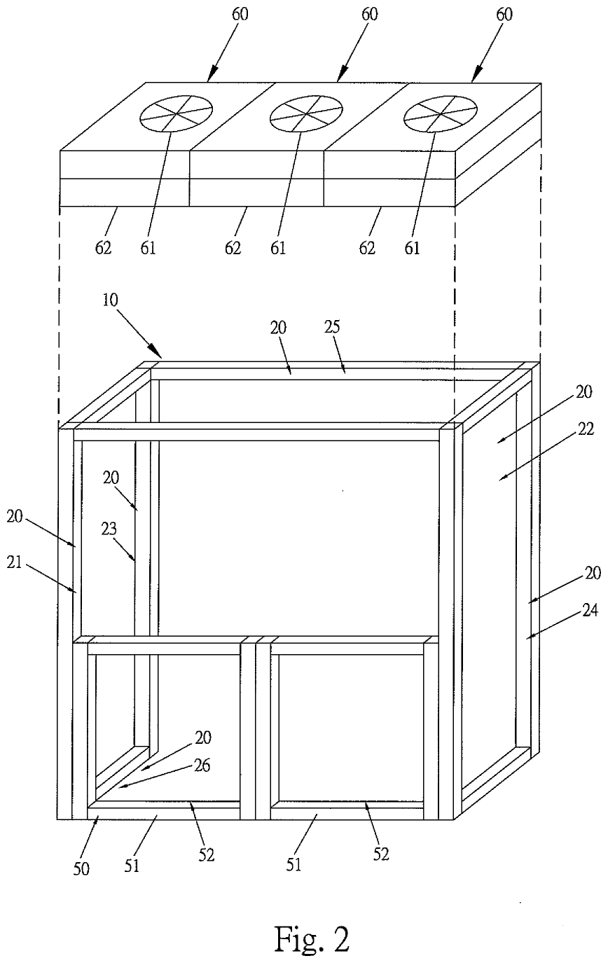

In the present invention, as illustrated in FIGS. 1 and 2, the outer frame 10 has a rectangular shape. Six surfaces of the outer frame 10 are opened with openings 20. The six surfaces includes a front opening 21, a back opening 22, a left opening 23, a right opening 24, an upper opening 25, and a lower opening 26.

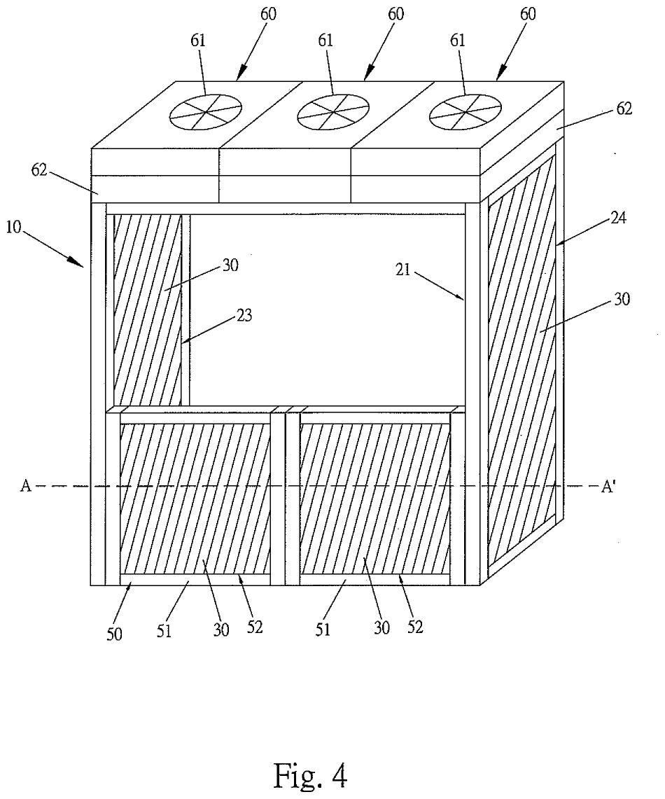

As illustrated in FIG. 4, in the present invention, at least one opening of the outer frame 10 may be installed with a fire proof plate 30. Other surfaces of the outer frame 10 are opened. For example, the surfaces of the outer frame 10 against walls or ground may be opened. Preferably, the specification of the fire proof plate 30 matches the requirement of FM-4910. A surface of the fire proof plate 30 may be coated with an anti-electric static layer 40 for preventing the generation of static electrons.

As shown in FIG. 4, the left opening 23 and the right opening 24 are sealed by respective fire proof plates 30. These fire proof plates 30 are coated with respective anti-electric static layers 40. Therefore, in application, the outer frame 10 may be installed against a wall, since the wall and ground do not induce fire and thus they are unnecessary to be installed with fire proof plates 30.

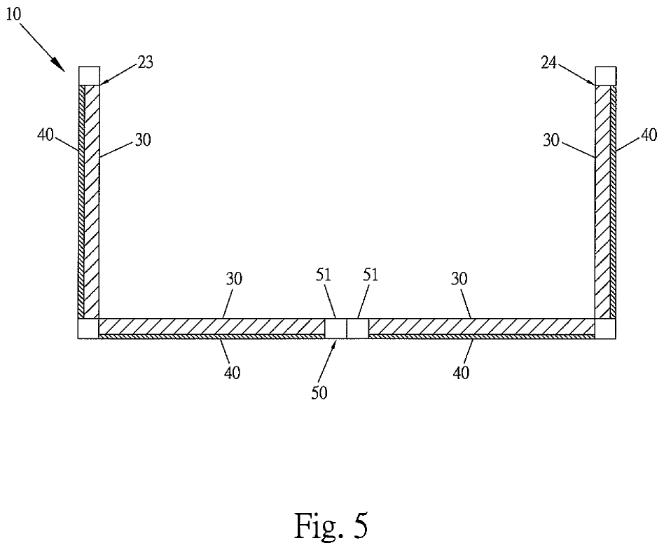

As shown in FIG. 5, the fire proof plates 30 are made of fire proof material which has the function of fire proof and high temperature prevention. The materials of the anti-electric static layer 40 are made of material for preventing generation of static electrons.

A door 50 is installed on the outer frame 10, preferably, on the front opening 21 of the outer frame 10. The door 50 includes two door plates 51. Each door plate 51 has a door opening 52 each of which is sealed by a fire proof plate 30. Therefore, when the door 50 is closed, it can seal an opening or at least one part of the outer frame 10. In this drawing, a lower side of the front opening 21 of the outer frame 10 is sealed by the door 50.

Surfaces of the fire proof plates 30 of the door 50 are coated with respective anti-electric static layers 40. The material of the fire proof plates 30 are made of fire proof material with functions of high temperature preventing and fire proof. The anti-electric static layers 40 of the fire proof plates 40 of the door 50 are made of anti-electric static material.

At least one air filter 60 is installed at an upper side of the outer frame 10 for sucking outer air into the outer frame 10. The air filter 60 includes at least one fan 61 and at least one filter device 62. The fan 61 serves to suck outer air into the filter device 62 for air filtering so as to flow out clean air. The clean air then flows to the mask machine. One example of the filtering device 60 is that it is an air filtering net which matches to the requirement of ULPA or HEPA.

At least one air filter 60 seals the upper opening 25 of the outer frame 10. The clean air flows through the mask machine 100 and then flow out from other openings of the outer frame 10.

In the embodiment of FIG. 1, it is illustrated that there are three air filters 60 which are installed on the upper side of the outer frame 10. Each fan 61 has a respective filter device 62 which is installed below the fan 61. However, the number of the fans 61 and the filter devices 62 are not confined to be three, it is adjustable as required.

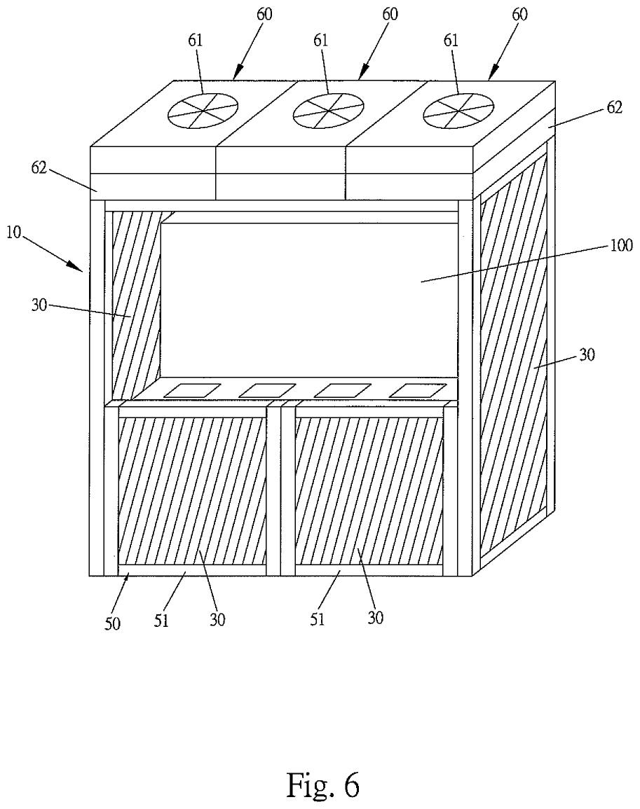

As illustrated in FIG. 6, in use, a mask machine 100 is installed within the outer frame 10. Cleaning air is necessary in operation of the mask machine 100. The air filter 60 serves to provide cleaned air to the mask machine 100. The fire proof plates 30 at outer side of the outer frame 10 have the function for endurance of high temperature and fire so as to protect the mask machine 100. The anti-electric static layers 40 on the surface of the fire proof plates 30 have the function of anti-electric statics so that the mask machine 100 is not affected by static electrons and thus can be operated normally without destroy.

Advantages of the present invention are that the outer frame is installed with air filter which serves to provide pure clean air of the mask machine. Outer sides of the outer frame are equipped with fire proof plates for preventing fire and increasing high temperature in the environment. Furthermore the fire proof plate is installed with an anti-electric static layer which has the function of preventing generation of static electrons so that the mask machine is not affected by static electrons. Therefore, the present invention provides a preferred environment to the operation of the mask machine.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A mask machine protection frame device with function of air filtering, comprising:
an outer frame being a hollow frame for receiving a mask machine therein; an outlook of the outer frame; and
at least one air filter installed at an upper side of the outer frame for sucking outer air into the outer frame; the air filter including at least one fan and at least one filter device; the fan serving to suck outer air into the filter device for air filtering so as to flow out clean air; and the clean air then flowing to the mask machine.

2. The mask machine protection frame device with function of air filtering as claimed in claim 1, wherein the outer frame is installed with at least one fire proof plate.

3. The mask machine protection frame device with function of air filtering as claimed in claim 2, wherein a surface of the fire proof plate is coated with an anti-electric static layer.

4. The mask machine protection frame device with function of air filtering as claimed in claim 1, wherein the outer frame has a rectangular shape; six surfaces of the outer frame are opened with openings which includes a front opening, a back opening, a left opening, a right opening, an upper opening, and a lower opening.

5. The mask machine protection frame device with function of air filtering as claimed in claim 1, wherein the left opening and the right opening are sealed by respective fire proof plates; and these fire proof plates are coated with respective anti-electric static layers.

6. The mask machine protection frame device with function of air filtering as claimed in claim 1, wherein a door is installed on the outer frame; and the door includes at least one door plate.

7. The mask machine protection frame device with function of air filtering as claimed in claim 6, wherein each door plate has a door opening each of which is sealed by a fire proof plate; and each fire proof plate is coated with an anti-electric static layer.

8. The mask machine protection frame device with function of air filtering as claimed in claim 2, wherein the specification of the fire proof plate matches requirements of FM-4910.

9. The mask machine protection frame device with function of air filtering as claimed in claim 5, wherein at least one air filter seals the upper opening of the outer frame.

10. The mask machine protection frame device with function of air filtering as claimed in claim 1, wherein each air filter includes at least one fan and at least one filtering device which is installed below the fan.

11. The mask machine protection frame device with function of air filtering as claimed in claim 10, wherein the filtering device is an air filtering net.

12. The mask machine protection frame device with function of air filtering as claimed in claim 11, wherein a specification of the air filtering net is ULPA or HEPA.
